(19) United States
(12) Patent Application Publication
(10) Pub. No.: US 2015/0299840 A1
(43) Pub. Date: Oct. 22, 2015

(54) MASK FRAME

(71) Applicant: Sharp Kabushiki Kaisha, Osaka (JP)

(72) Inventors: Tomofumi Osaki, Osaka (JP); Shinichi Kawato, Osaka (JP); Takashi Ochi, Osaka (JP); Katsuhiro Kikuchi, Osaka (JP); Manabu Niboshi, Osaka (JP); Tomohiro Kosaka, Osaka (JP); Yuto Tsukamoto, Osaka (JP)

(73) Assignee: Sharp Kabushiki Kaisha, Osaka (JP)

(21) Appl. No.: 14/411,383

(22) PCT Filed: Jun. 19, 2013
(86) PCT No.: PCT/JP2013/066802

§ 371 Date: Dec. 24, 2014

(30) Foreign Application Priority Data
Jun. 26, 2012 (JP) 2012-143504

(51) Int. Cl. C23C 14/04

(52) U.S. Cl. CPC C23C 14/042

(57) ABSTRACT

A mask frame according to one embodiment of the present invention includes a side with a surface having a shape of a mountain that has the highest point at a center in the lengthwise direction thereof and respective lowest points at an end and another end in the lengthwise direction, and a side facing the side and having the same shape as the side.

### TECHNICAL FIELD

The present invention relates to a mask frame to which a metal mask for depositing materials on a substrate is attached.

### BACKGROUND ART

A metal mask for depositing materials on a substrate is used when manufacturing organic EL displays. The metal mask is made of metal and attaches to the mask frame. The metal mask is ordinarily welded to the surface of the mask frame.

In recent years, organic EL displays have been increasing in size as technology progresses. The metal mask and mask frame have also increased in size to accommodate this. On the other hand, there is demand for the metal mask to be thinner in order to precisely deposit materials on the substrate. The thickness of current metal masks is approximately several dozen to several hundred micrometers.

FIG. 5(a) schematically shows material being deposited onto a substrate 104 using a conventional mask frame 101 and metal mask 102. The mask frame 101 is a metal frame that has a large opening in the center thereof. The metal mask 102 is welded to a surface of the mask frame 101. The metal mask 102 is welded to the surface of at least one pair of sides forming a portion of the mask frame 101. All four sides may be welded. In any case, only the periphery of the metal mask 102 is welded to the mask frame 101. Accordingly, the area of the metal mask 102 facing the opening in the mask frame 101 does not contact the mask frame 101.

In an evaporation apparatus, the mask frame 101 and the metal mask 102 are arranged parallel to the ground. The metal mask 102 is welded to the surface of the mask frame 101 opposite to the ground. The welding surface of the metal mask 102 lies within a single plane, and thus the metal mask 102 is welded to the welding surface in a thin flat shape.

The substrate 104 is disposed on top of the metal mask 102. A large number of openings are provided in the metal mask 102 corresponding to the material deposition patterns for the substrate 104. An evaporation source 106 is provided at a location that is a uniform distance from the mask frame 101 and that faces the surface of the mask frame 101 opposite to the deposition surface. Materials for forming organic EL elements or the like are emitted from the evaporation source 106 towards the openings in the metal mask 102. This deposits the materials onto the substrate 104 through the openings in the metal mask 102. As a result, prescribed patterns are formed on the substrate 104.

FIG. 5(b) shows a cross section of the conventional mask frame 101 and a cross section of the metal mask 102 attached to the mask frame 101.

As described above, the metal mask 102 is very thin. Accordingly, if the metal mask 102 is made larger, the metal mask 102 will bend towards the ground due to the weight thereof in a location of the mask frame 101 facing the substrate 104. As shown in FIG. 5(b), the force exerted on the metal mask 102 due to the weight thereof becomes progressively greater towards the center of the metal mask 102, and the bend becomes correspondingly larger.

If the metal mask 102 has a significant bend as shown FIG. 5(b), then the pre-made openings in the metal mask 102 will no longer face the substrate with the specifically designed size and shape thereof. Accordingly, there is a risk that the patterns deposited on the substrate 104 through these holes could deviate from design. It is also possible that materials could be deposited through an opening onto a location of the substrate 104 corresponding to an adjacent opening.

When manufacturing an organic EL display, the individual openings in the metal mask 102 correspond to individual pixels on the substrate 104. Thus, when using the metal mask 102 and the mask frame 101 shown in FIG. 5(a), a group of pixels having a pattern that is different than the design pattern will be formed on the substrate 104. The material for these pixels will also mix with adjacent pixels. These factors make the manufactured organic EL display susceptible to decreases in display quality, blacking out of pixels on some parts of the display, and the like.

In order to solve these problems, a technique has been previously proposed for reducing the bending of the metal mask caused by the weight thereof during substrate deposition. Patent Document 1 discloses an evaporation apparatus having a pressing mechanism that presses a substrate on which a film will be formed (target substrate) placed on an evaporation mask to the evaporation mask. This evaporation apparatus has magnets at least on locations corresponding to the corners of the target substrate. The aim of this evaporation apparatus is to reduce deformation of the evaporation mask caused by the weight thereof by the magnets pulling the evaporation mask in the direction opposite to the direction of gravitational force.

### RELATED ART DOCUMENT

### Patent Document

Patent Document 1: Japanese Patent Application Laid-Open Publication, “Japanese Patent Application Laid-Open Publication No. 2011-233510 (Published on Nov. 17, 2011)”

### SUMMARY OF THE INVENTION

### Problems to be Solved by the Invention

The technology in Patent Document 1, however, does not change how the center portion of the evaporation mask bends due to the weight thereof. When using a large-sized evaporation mask, in particular, the technology in Patent Document 1 cannot sufficiently reduce bending of the evaporation mask. Procedures are also necessary for preventing the magnets from having adverse effects on other members of the evaporation apparatus. These procedures require additional members and risk enlarging and complicating the evaporation apparatus.

The present invention was made to solve the above-mentioned problems. According to one aspect of the present invention, it is possible to effectively reduce bending of the metal mask caused by the freedom thereof, without requiring additional members.

### Means for Solving the Problems

To solve the above-mentioned problems, a mask frame according to the present invention is a rectangular mask frame having an opening therein and to which an evaporation mask attaches, including:

a first side with a surface having a shape of a mountain that has a highest point at a center in a lengthwise direction thereof and respective lowest points at an end and another end in the lengthwise direction;

a second side facing the first side and having the same shape as the first side;

a third side orthogonal to the first side and the second side; and

a fourth side facing the third side.

### Effects of the Invention

The mask frame according to one aspect of the present invention has effects that make it possible to effectively reduce bending of the metal mask caused by the freedom thereof, without requiring additional members.

### BRIEF DESCRIPTION OF THE DRAWINGS

FIG. 1(a) is an external view of a mask frame according to Embodiment 1 of the present invention.

FIG. 1(b) is a cross section of the mask frame of Embodiment 1 and a cross section of a metal mask attached to this mask frame.

FIG. 2 is a schematic view of materials being deposited on a substrate 4 using a mask frame 1 and a metal mask 2 of Embodiment 1 of the present invention.

FIG. 3(a) is a view of deposition when the metal mask is significantly bent.

FIG. 3(b) is a view of deposition when the metal mask is not bent at all.

FIG. 4(a) is an external view of a mask frame according to Embodiment 2 of the present invention.

FIG. 4(b) is an external view of a mask frame according to Embodiment 2 of the present invention.

FIG. 4(c) is an external view of a mask frame according to Embodiment 2 of the present invention.

FIG. 5(a) is a schematic view of materials being deposited onto a substrate using a conventional mask frame and metal mask, and FIG. 5(b) is a cross section of the conventional mask frame and a cross section of the metal mask attached to this mask frame.

### DETAILED DESCRIPTION OF EMBODIMENTS

### Embodiment 1

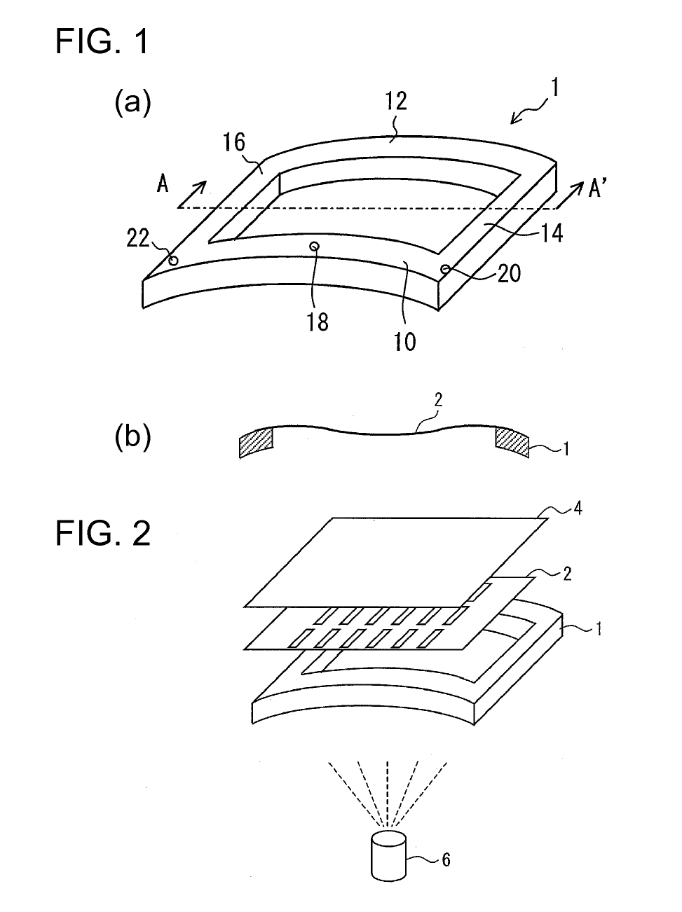

An embodiment of the present invention will be explained below with reference to FIGS. 1 to 3.

FIG. 2 is a schematic view of materials being deposited on a substrate 4 using a mask frame 1 and a metal mask 2 of the present embodiment.

(Mask Frame 1)

The mask frame 1 is a rectangular metal frame that has a large opening in the center thereof. The mask frame 1 is used to secure and stabilize the metal mask 2. In the present embodiment, the mask frame 1 has a rectangular shape. The mask frame 1, however, may have a square shape. The shape of the mask frame 1 is determined in accordance with the shape of the substrate 4 for deposition.

The mask frame has a frame that is constituted of four narrow sides. The width and the thickness of the frame are approximately several dozen millimeters in order to ensure sufficient strength. Therefore, even if the mask frame 1 is made larger, the mask frame 1 will not bend or deform due to the weight thereof.

The metal mask 2 (evaporation mask) is attached to a surface of the mask frame 1. As described in detail later, the metal mask 2 is not flat, but rather a curved shape. This reduces bending of the metal mask 2.

(Metal Mask 2)

The metal mask 2 is an evaporation mask used for forming thin films having prescribed patterns on the substrate 4. The metal mask 2 is made of metal and has a thin rectangular shape. The thickness of the metal mask is approximately several dozen to several hundred micrometers. In the present embodiment, the metal mask 2 has a rectangular shape. The metal mask 2, however, may have a square shape. The shape of the metal mask 2 is determined by the use thereof. When the metal mask is used to deposit materials on a large-sized substrate 4, for example, it is preferable that the metal mask 2 have a thin rectangular shape. This is because if a plurality of the thin rectangular metal masks 2 are arranged in a row and attached to the mask frame 2, then it is not necessary to have a large-sized metal mask 2 that corresponds to the large sized substrate 4.

The metal mask 2 attaches to the mask frame 1 by being welded to at least a pair of mutually facing sides of the mask frame 1. All four sides may be welded, however. In any case, only the periphery of the metal mask 2 is welded to the mask frame 1. Accordingly, the area of the metal mask 2 facing the opening in the mask frame 2 is not welded to the mask frame 1.

A large number of openings are provided in areas of the metal mask 2 corresponding to the opening in the mask frame 1, and these openings in the metal mask correspond to the material deposition patterns for the substrate 4. The size of the individual openings is determined by the use of the individual thin films deposited on the substrate 4.

(Substrate 4)

The substrate 4 is a substrate on which a film will be formed (target substrate), and a thin film having a prescribed pattern is formed thereon through the openings in the metal mask 2. In the present embodiment, the substrate 4 forms a portion of an organic EL display. The patterns formed on the substrate 4 through the metal mask 2 are pixel patterns for an organic EL display.

(Evaporation Source 6)

The evaporation source 6 emits the materials that will be deposited onto the substrate 4. In the present embodiment, organic light emitting materials that form the pixels of an organic EL display are emitted towards the metal mask 2, for example. This deposits the materials onto the substrate 4 through the openings in the metal mask 2. As a result, the emitted materials are deposited onto the substrate 4 in prescribed patterns.

(Arrangement of Members)

As shown in FIG. 2, the metal mask 2 is attached to one surface of the metal mask 2. This surface is also called the deposition surface. The substrate 4 is disposed on top of the metal mask 2. The substrate 4 is provided parallel to the ground. The evaporation source 6 is provided at a location that is a uniform distance from the mask frame 1 and that faces the surface of the mask frame opposite to the deposition surface. The evaporation source 6 causes materials to be deposited onto the substrate 4 provided above the evaporation source 6 by emitting these materials upwards.

(Details of Mask Frame 1)

FIG. 1(a) is an external view of the mask frame 1 of the present embodiment. As shown in the drawing, the mask frame 1 is constituted of a side 10 (first side), a side 12 (second side), a side 14 (third side), and a side 16 (fourth side).

The side 10 has a mountain-like surface in which a center 18 in the lengthwise direction of the side 10 is the top, and an end 20 and an end 22 in the lengthwise direction of the side 10 are each the bottom. This surface is the side to which the metal mask 2 attaches. The side 10 itself has a mountain-like shape. In the present embodiment, the shape of the surface of the side 10 has an arc shape or a cosine shape that connects the center 18 to the end 20 and the end 22. In other words, the surface of the side 10 is curved.

The side 12 faces the side 10 and has a similar shape thereto. In other words, the surface of the side 12 also has a mountain-like shape, which is the same as the surface of the side 10. The side 12 itself also has a mountain-like shape.

The side 14 is orthogonal to the side 10 and the side 12. The surface of the side 14 is curved in a similar manner to the surface of the side 10 near the end 20.

The side 16 faces the side 14 and is orthogonal to the side 10 and the side 12. The surface of the side 16 is curved in a similar manner to the surface of the side 10 near the end 22.

In the present embodiment, the side 10 and the side 12 are longer than the side 14 and the side 16. In other words, the side 10 and the side 12 are the pair of long sides of the mask frame 1, and the side 14 and the side 16 are the pair of short sides of the mask frame 1. This is merely an example, however. The side 10 and the side 12 may be the same length as the side 14 and the side 16.

The metal mask 2 attaches to the mask frame 1a by being welded on at least the side 14 and the side 16. The metal mask 2 may be welded onto the surface of the side 10 and the surface of the side 12, or may not be welded on these surfaces. If the metal mask 2 is not welded onto the surface of the side 10 and the surface of the side 12, then the area of the metal mask 2 facing the side 10 is proximate to the side 10, but strictly speaking, is not in contact with the side 10. In a similar manner, the area of the metal mask 2 facing the side 12 is proximate to the side 12, but strictly speaking, is not in contact with the side 12.

(Reducing Bending of Metal Mask 2)

FIG. 1(b) is a cross section of the mask frame 1 of the present embodiment and a cross section of the metal mask 2 attached to the mask frame 1. As described above, the side 10 has a mountain-like shape with the center 18 in the lengthwise direction as the top. The side 12 has the same shape as the side 10. Accordingly, the metal mask 2 attached to the mask frame 1 curves in a direction opposite to the ground along the surface of the side 10 and the side 12. Therefore, the force exerted on the metal mask 2 by this curve is exactly opposite to the force exerted on the metal mask by the weight thereof; thus, as shown in FIG. 1(b), it is possible to reduce the bending of the metal mask 2 due to the weight thereof.

The metal mask 2 can be attached so as to perfectly follow the surface of the side 10 and the surface of the side 12. Therefore, it is possible to stably maintain the metal mask 2 in the curved state thereof. This makes it possible to prevent the metal mask 2 from deforming once attached.

Furthermore, as shown in FIG. 1(b), the periphery of the metal mask 2 is welded to the curved surface of the side 14 and the curved surface of the side 16. This makes it possible to further impart the force attempting to bend the metal mask into a mountain-like shape to the metal mask. Accordingly, the bending of the metal mask 2 due to the freedom thereof can be further reduced. The surface of the side 14 and the side 16 may be horizontally flat, instead of curved.

(Deposition Accuracy)

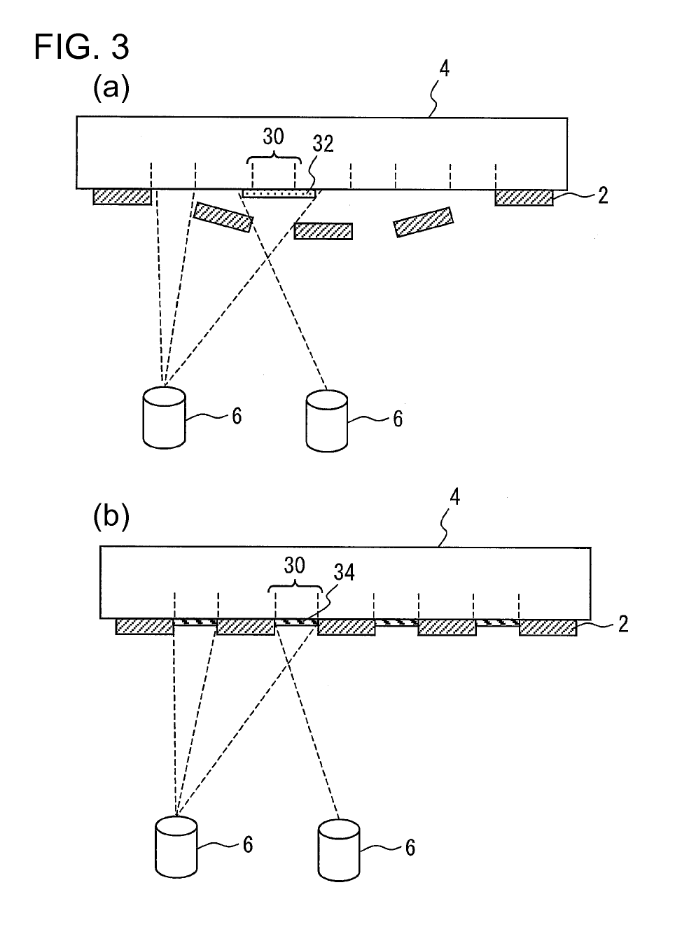

FIG. 3(a) is a view of deposition when the metal mask 2 is significantly bent. As shown in FIG. 3(a), if the metal mask 2 bends significantly due to the weight thereof, the metal mask 2 is not disposed parallel to the substrate 4. Specifically, the metal mask 2 becomes progressively farther from the substrate 4 and closer to the ground towards the center of the metal mask 2. Due to this, it becomes impossible to deposit materials on a target deposition area 30 of the substrate 4. Therefore, a thin film 32 formed on the substrate 4 becomes wider than the deposition area 30. As a result, a group of pixels that have a different pattern than originally designed are formed on the substrate 104. Material for certain pixels also mixes with adjacent pixels. These factors make the manufactured organic EL display susceptible to decreases in display quality, blacking out of pixels on some parts of the display, and the like.

FIG. 3(b) is a view of deposition when the metal mask 2 is not bent at all. As shown in FIG. 3(b), if the metal mask 2 is not bent significantly due to the weight thereof, the metal mask 2 is disposed parallel to the substrate 4. Specifically, any position on the metal mask 2 is at a uniform distance to the substrate 4. This makes it possible to accurately deposit the materials onto the target deposition area 30 of the substrate 4. As a result, a thin film 34 formed on the substrate 4 perfectly fits the deposition area 30. This results in pixels being able to be formed on the substrate 104 with the specific designed pattern thereof. Accordingly, the manufactured organic EL display will not be susceptible to decreases in display quality, blacking out of pixels on some parts of the display, and the like.

In the present embodiment, the force that curves the metal mask 2 in the direction opposite to the ground is always being exerted. Thus, it is impossible to attach the metal mask 2 to the mask frame 1 in a completely flat state. The bending of the metal mask 2 attached to the mask frame 1 of the present embodiment, however, is markedly less than the bending of the metal mask 102 of the mask frame 101 according to the conventional technology. In other words, a situation such as that shown in FIG. 3(a) is likely to occur during evaporation that uses the mask frame 101 of the conventional technology, whereas a situation such as that shown in FIG. 3(b) is likely to occur during evaporation that uses the mask frame 1 of the present embodiment. Therefore, even if an ideal deposition accuracy cannot be obtained with the mask frame 1 of the present embodiment, the deposition accuracy will still be sufficiently higher than the conventional technology.

The mask frame 1 of the present embodiment does not require additional members such as magnets in order to reduce the bending of the metal mask 2 due to the weight thereof. Thus, there are no adverse effects on the evaporation apparatus during the deposition process.

(Deposition Direction)

In the example shown in FIG. 2, evaporation is performed by the substrate 4 being disposed above the metal mask 2 and material being emitted upwards from the evaporation source 6 positioned below the metal mask 2. This is merely an example, however. In other words, evaporation may be performed by the substrate 4 being disposed below the metal mask 2 and the material being emitted downwards from the evaporation source 6 positioned above the metal mask 2. In any case, the metal mask 2 is arranged horizontally, and thus it is possible to reduce the bending of the metal mask 2 due to the weight thereof.

(Deposition Areas)

The portion of the metal mask 2 attached to the mask frame 1 adjacent to the mountain-shaped side 10 and side 12 is curved along the side 10 and the side 12. Therefore, if materials are deposited using areas of the metal mask 2 that are too close to the side 10 and the side 12, then it will be difficult to accurately deposit these materials on the flat substrate 4. It is preferable that the areas of the metal mask 2 used for deposition be close to the center and more inside than the mask frame 1 on which the metal mask 2 is placed. This makes it possible to prevent a drop in deposition accuracy.

### Embodiment 2

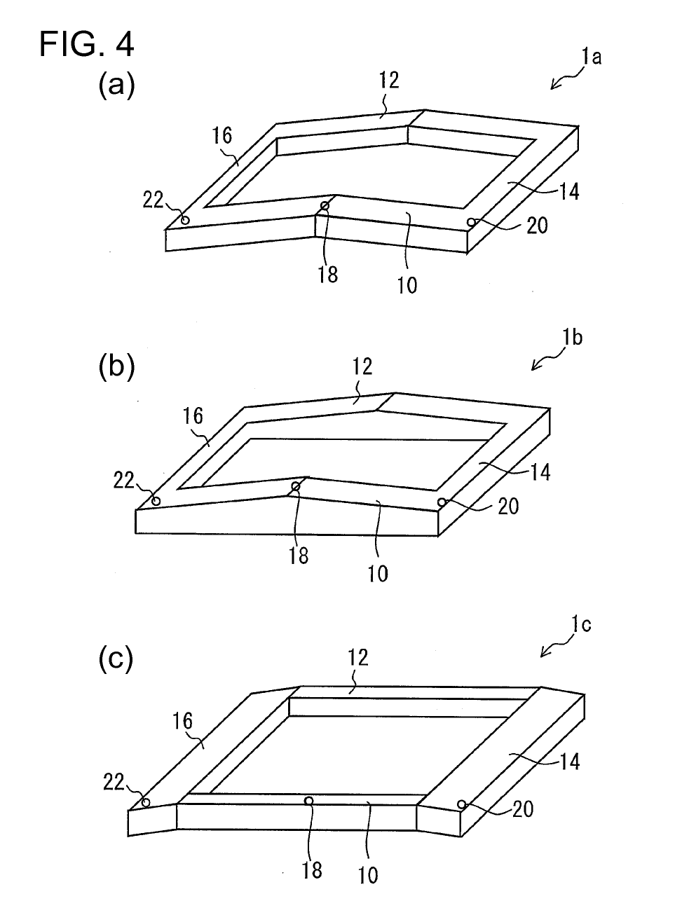

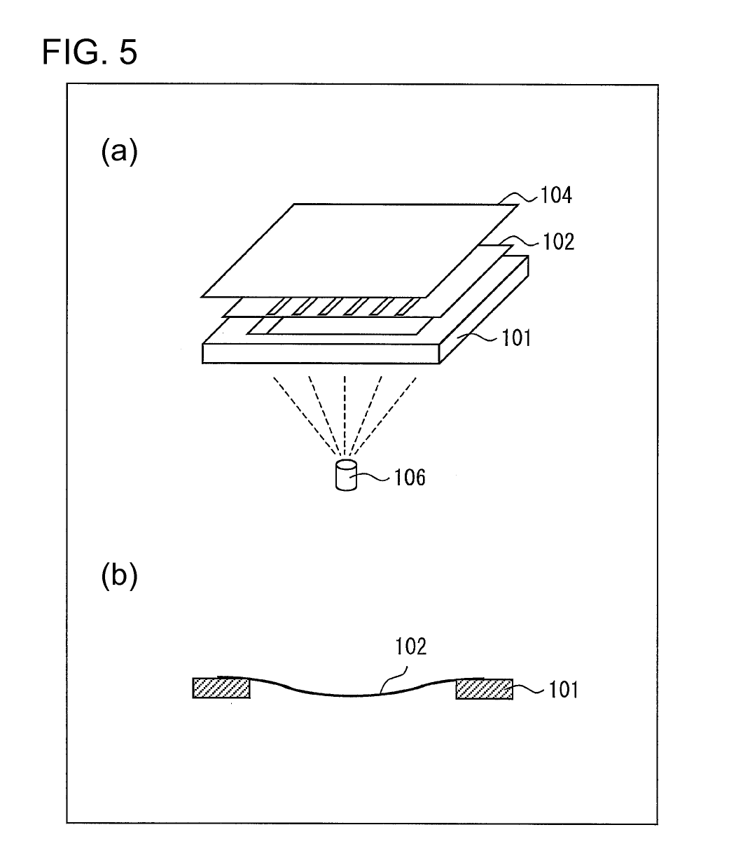

Embodiment 2 of the present invention will be explained below with reference to FIG. 4. The same reference characters are given to the respective members that are the same as in Embodiment 1 described above, and a detailed explanation thereof will not be repeated.

(Mask Frame 1a)

FIG. 4(a) is an external view of a mask frame 1a of Embodiment 2. The mask frame 1a is constituted of two semi-rectangular metal members. One of the metal members is constituted of half of a side 10, half of a side 12, and a side 14. The other metal member is constituted of the other half of the side 10, the other half of the side 12, and a side 14.

As shown in FIG. 4(a), the surface of the side 14 of the mask frame 1a is constituted of a slanted face (first slanted portion) that slants from the center 18 towards an end 20, and a slanted face (second slanted portion) that slants from the center 18 towards the end 22. In other words, the surface of the side 10 is not an arc shape or a cosine shape. The side 10 itself, however, has a mountain-like shape, in a manner similar to the side 10 of the mask frame 1 of Embodiment 1.

The side 12 has a shape that is similar to the side 10. In other words, the side 12 also has a mountain-like shape. The side 10 and the side 12 are parallel to each other.

The surface of the side 14 is constituted of a slanted face (third slanted portion) that has the same slant angle as the surface near the end 20. Meanwhile, the surface of the side 16 is constituted of a slanted face (fourth slanted portion) that has the same slant angle as the surface near the end 22. The metal mask 2 attaches to the mask frame 1a by being welded on at least the side 14 and the side 16. The metal mask 2 may be welded onto the surface of the side 10 and the surface of the side 12, or may not be welded on these surfaces.

The area of the metal mask 2 to be welded to the side 14 is welded to the side 14 while slanted along the slanted surface of the side 14. Meanwhile, the area of the metal mask 2 to be welded to the side 16 is welded to the side 16 while slanted along the slanted surface of the side 16. The welded areas of the metal mask 2 being slanted in this manner exerts force on the metal mask 2, which causes the metal mask 2 to be curved in the direction opposite to the ground. The side 12 and the side 14 both having a mountain-like shape places the center of the metal mask 2 further away from the end and further away from the ground. This also exerts force that causes the metal mask 2 to curve in the direction opposite to the ground.

Accordingly, with the mask frame 1a, the force trying to bend the metal mask 2 towards the ground due to the weight thereof is weakened by the force trying to curve the metal mask 2 in the direction opposite to the ground. As a result, the mask frame 1a also has an effect of reducing bending of the metal mask 2 due to the weight thereof, in a similar manner to the mask frame 1.

The mask frame 1 shown in FIG. 4(a) is formed by two semi-rectangular metal members that each have rectangular metal bars bent at an angle in two locations. There is absolutely no curve on either of the metal members. Accordingly, forming these types of metal members through the processing of metal materials is easier than forming the mask frame 1 having the curved surface as shown in FIG. 1. Thus, the number of members of the mask frame 1a shown in FIG. 4(a) increases, but the manufacturing thereof is easier.

(Mask Frame 1b)

FIG. 4(b) is an external view of a mask frame 1b of Embodiment 2. The mask frame 1b is constituted of one frame-shaped metal member. The surface of the side 14 of the mask frame 1b is constituted of a first slanted portion that slants from a center 18 towards an end 20, and a second slanted portion that slants from the center 18 towards an end 22. In other words, the surface of the side 10 is not an arc shape or a cosine shape. The side 10 itself, however, has a mountain-like shape, in a manner similar to the side 10 of the mask frame 1 of Embodiment 1.

The side 12 has a shape that is similar to the side 10. In other words, the side 12 also has a mountain-like shape. The side 10 and the side 12 are parallel to each other.

The surface of the side 14 is a slanted surface that has the same tilt as the surface of the side 10 near the end 20. Meanwhile, the surface of the side 16 is a slanted surface that has the same tilt as the surface of the side 10 near the end 22. The metal mask 2 attaches to the mask frame 1b by being welded on at least the side 14 and the side 16. The metal mask 2 may be welded onto the surface of the side 10 and the surface of the side 12, or may not be welded on these surfaces.

As described above, the welding surface of the mask frame 1b is essentially the same as the welding surface of the mask frame 1a. Therefore, the mask frame 1b also has an effect of reducing the bending of the metal mask 2 due to the weight thereof, in a manner similar to the mask frame 1a and the mask frame 1.

In the mask frame 1b, the side 10, the side 12, the side 14, and the side 16 are integrally formed. The respective side faces of the side 10, the side 12, the side 14, and the side 16 are all planar surfaces. The respective rear surfaces of the side 10, the side 12, the side 14, and the side 16 are included in one plane. In this manner, the mask frame 1b has no slanted surface at all. There is absolutely no curved surface, unlike the mask frame 1 shown in FIG. 1(a). In other words, the mask frame 1b is easier to manufacture form metal materials than the mask frame 1. The mask frame 1b also has fewer members than the mask frame in FIG. 4(a).

(Mask Frame 1c)

FIG. 4(c) is an external view of a mask frame 1c of Embodiment 2. The mask frame 1a is constituted of first to fourth rectangular metal members. The first metal member has a portion of the side 10 contacting the opening. The second metal member has a corner including the end 20 of the side 10, all of the side 12, and a corner including an end of the side 14 opposite to the end 20. The third metal member has a portion of the side 12 contacting the opening. The fourth metal member has a corner including the end 22 of the side 10, all of the side 16, and a corner including an end of the side 14 opposite to the end 22.

As shown in FIG. 4(c), the surface of the first metal member of the mask frame 1c is not slanted. In other words, the surface of the first metal member is a uniform plane. Due to this, the surface of the side 10 is constituted of a planar surface that contacts one side of the opening, a slanted surface (fifth slanted portion) that slants from one side of the two sides that are orthogonal to the length direction of this planar surface to the end 20, and a slanted surface (sixth slanted portion) that slants from the other side of the two sides to the end 22. In other words, the surface of the side 10 is not an arc shape or a cosine shape. The side 10 itself has a mountain-like shape in which the entire planar surface contacting a side of the opening is the top, and the end 20 and the end 22 are each the bottom.

The side 12 has a shape that is similar to the side 10. In other words, the side 12 also has a mountain-like shape. The side 10 and the side 12 are parallel to each other.

The surface of the side 14 is a slanted surface that has the same tilt as the surface near the end 20. Meanwhile, the surface of the side 16 is a slanted surface that has the same tilt as the surface near the end 22. The metal mask 2 attaches to the mask frame 1a by being welded on at least the side 14 and the side 16. The metal mask 2 may be welded onto the surface of the side 10 and the surface of the side 12, or may not be welded on these surfaces.

The area of the metal mask 2 to be welded to the side 14 is welded to the side 14 while slanted along the slanted surface of the side 14. Meanwhile, the area of the metal mask 2 to be welded to the side 16 is welded to the side 16 while slanted along the slanted surface of the side 16. The welded areas of the metal mask 2 being slanted in this manner exerts force on the metal mask 2, which causes the metal mask 2 to be curved in the direction opposite to the ground.

Accordingly, with the mask frame 1c, the force trying to bend the metal mask 2 towards the ground due to the weight thereof is weakened by the force trying to curve the metal mask 2 in the direction opposite to the ground. As a result, the mask frame 1c also has an effect of reducing bending of the metal mask 2 due to the weight thereof, in a similar manner to the mask frame 1.

In an evaporation apparatus where the metal mask 2 and the substrate 4 do not move relative to each other, deposition accuracy can be increased by depositing materials while the substrate 4 is adhered to the metal mask 2. In an evaporation apparatus where the metal mask 2 and the substrate 4 move relative to each other, it is necessary to provide a uniform gap between the substrate 4 and the metal mask 2, but the smaller the gap is, the more the deposition accuracy can be increased.

In the mask frame 1c, the surface of the side 10 in contact with a side of the opening is not slanted towards the ground, but is uniformly planar. In a similar manner, the surface of the side 12 in contact with a side of the opening is not slanted towards the ground, but is uniformly planar. In other words, the opening in the mask frame 1c is parallel to the substrate 4 as a whole. Accordingly, it is possible to adhere the substrate 4 to the metal mask 2 or to make the gap between the substrate 4 and the metal mask 2 as small as possible. In other words, the deposition accuracy of the mask frame 1c can be increased more than the mask frames 1, 1a, and 1b.

The mask frame 1 shown in FIG. 4(a) is constituted of four rectangular metal members. There is absolutely no curve on any of the metal members. Accordingly, forming these types of metal members through the processing of metal materials is easier than forming the mask frame 1 having the curved surface as shown in FIG. 1. Thus, the number of members of the mask frame 1a shown in FIG. 4(a) increases, but the manufacturing thereof is easy.

The present invention is not limited to the embodiments above. Various modifications can be made to the present invention by those skilled in the art without departing from the scope specified by claims. That is, new embodiments can be obtained by combining technologies that were appropriately modified in the scope specified by claims.

### Summary

A mask frame according to the present invention is a rectangular mask frame having an opening therein and to which an evaporation mask attaches, including:

a first side with a surface having a shape of a mountain that has a highest point at a center in a lengthwise direction thereof and respective lowest points at an end and another end in the lengthwise direction;

a second side facing the first side and having the same shape as the first side;

a third side orthogonal to the first side and the second side; and

a fourth side facing the third side.

With this configuration, the first side and the second side have a mountain-like shape in which a center in the lengthwise direction thereof is the top. Accordingly, the metal mask attached to the mask frame according to one aspect of the present invention curves along this mountain-like shape. The force exerted on the metal mask by this curve is the complete opposite of the force exerted on the metal mask by the weight thereof. Thus, it is possible to reduce bending of the metal mask caused by the weight thereof.

The mask frame according to one aspect of the present invention does not require additional members such as magnets in order to reduce the bending of the metal mask due to the weight thereof. Thus, it is not necessary to make the evaporation apparatus having this mask frame larger or to complicate this apparatus.

In regards to the mask frame according to one aspect of the present invention, it is preferable that the surface of the first side be a circular arc shape or a cosine shape connecting the center of the first side to a first end and a second end.

With this configuration, the metal mask can be attached so as to perfectly fit along the surface of the first side and the second side. Therefore, it is possible to stably maintain the metal mask in the curved state thereof. This makes it possible to prevent the metal mask from deforming once attached.

In regards to the mask frame according to one aspect of the present invention, it is preferable that a surface of the third side have a curved portion that is smoothly connected to the surface of the first side near the first end, and a surface of the fourth side have a curved portion that is smoothly connected to the surface of the first side near the second end.

With this configuration, the periphery of the metal mask is welded to the third side and the fourth side, thereby allowing for more of the force attempting to curve the metal mask in a mountain-like shape to be imparted on the metal mask.

In regards to the mask frame according to one aspect of the present invention, the surface of the first side is constituted of a first slanted portion that slants from the center of the first side to one end, and a second slanted portion that slants from the center of the first side to another end.

With this configuration, the mask frame according to one aspect of the present invention can be easier to manufacture.

In regards to the mask frame according to one aspect of the present invention, it is preferable that a surface of the third side be constituted of a slanted portion that slants orthogonally to a length direction of the third side and that has the same tilt angle as the first slanted portion, and a surface of the fourth side be constituted of a slanted portion that slants orthogonally to a length direction of the fourth side and that has the same tilt angle as the second slanted portion.

With this configuration, the mask frame according to one aspect of the present invention can be easier to manufacture.

In regards to the mask frame according to one aspect of the present invention, the surface of the first side is constituted of: a planar surface portion that is in contact with a side of the opening; a fifth slanted portion that slants from one of two sides orthogonal to a length direction of the planar surface portion towards one of the ends; and a sixth slanted portion that slants from another side of the two sides towards the other end.

With this configuration, the mask frame according to one aspect of the present invention can be easier to manufacture.

In regards to the mask frame according to one aspect of the present invention, it is preferable that the first side, the second side, the third side, and fourth side be integrally formed, respective side faces of the first side, the second side, the third side, and the fourth side be planar surfaces, and respective rear surfaces of the first side, the second side, the third side, and fourth side be included in one planar surface.

In regards to the mask frame according to one aspect of the present invention, it is preferable that the first side be longer than the third side.

With this configuration, the shape of the mask frame is rectangular. Therefore, it is possible to deposit materials on a rectangular substrate.

### INDUSTRIAL APPLICABILITY

A mask frame according to the present invention can be widely used as various types of mask frames to which an evaporation metal mask is attached.

### DESCRIPTION OF REFERENCE CHARACTERS

1 mask frame

2 metal mask

4 substrate

6 evaporation source

10 side (first side)

12 side (second side)

14 side (third side)

16 side (fourth side)

18 center

20 end (first end)

22 end (second end)

1. A rectangular mask frame having an opening therein and to which an evaporation mask attaches, comprising:
a first side with a surface having a shape of a mountain that has a highest point at a center in a lengthwise direction thereof and respective lowest points at an end and another end in said lengthwise direction;
a second side facing the first side and having the same shape as the first side;
a third side orthogonal to the first side and the second side; and
a fourth side facing the third side.

2. The mask frame according to claim 1, wherein the surface of the first side is a circular arc shape or a cosine shape connecting the center of the first side to a first end and a second end.

3. The mask frame according to claim 2,
wherein a surface of the third side has a curved portion that is smoothly connected to the surface of the first side near the first end, and
wherein a surface of the fourth side has a curved portion that is smoothly connected to the surface of the first side near the second end.

4. The mask frame according to claim 1, wherein the surface of the first side is constituted of a first slanted portion that slants from the center of the first side to one end, and a second slanted portion that slants from the center of the first side to another end.

5. The mask frame according to claim 4,
wherein a surface of the third side is constituted of a slanted portion that slants orthogonally to a length direction of the third side and that has the same tilt angle as the first slanted portion, and
wherein a surface of the fourth side is constituted of a slanted portion that slants orthogonally to a length direction of the fourth side and that has the same tilt angle as the second slanted portion.

6. The mask frame according to claim 1, wherein the surface of the first side is constituted of: a planar surface portion that is in contact with a side of a rectangular shape defined by the opening; a first slanted portion that slants from one end of the planar surface portion towards one of the ends of the first side; and a second slanted portion that slants from another end of the planar surface portion towards the other end of the first side.

7. The mask frame according to claim 6,
wherein the first side, the second side, the third side, and fourth side are integrally formed,
wherein respective side faces of the first side, the second side, the third side, and the fourth side are planar surfaces, and
wherein respective rear surfaces of the first side, the second side, the third side, and fourth side are included in one planar surface.

8. The mask frame according to claim 1, wherein the first side is longer than the third side.

9. The mask frame according to claim 2, wherein the first side is longer than the third side.

10. The mask frame according to claim 3, wherein the first side is longer than the third side.

11. The mask frame according to claim 4, wherein the first side is longer than the third side.

12. The mask frame according to claim 5, wherein the first side is longer than the third side.

13. The mask frame according to claim 6, wherein the first side is longer than the third side.

14. The mask frame according to claim 7, wherein the first side is longer than the third side.
